(19) United States
(12) Patent Application Publication
(10) Pub. No.: US 2024/0204258 A1
(43) Pub. Date: Jun. 20, 2024

(54) METHOD FOR INSPECTING BATTERY AND METHOD FOR PRODUCING BATTERY

(71) Applicant: TOYOTA JIDOSHA KABUSHIKI KAISHA, Toyota-shi (JP)

(72) Inventors: Toshinori OKURA, Toyota-shi (JP); Kiwamu KOBAYASHI, Anjo-shi (JP); Tadashi TERANISHI, Toyota-shi (JP); Hideto MORI, Nisshin-shi (JP)

(73) Assignee: TOYOTA JIDOSHA KABUSHIKI KAISHA, Toyota-shi (JP)

(21) Appl. No.: 18/532,664

(22) Filed: Dec. 7, 2023

(30) Foreign Application Priority Data
Dec. 14, 2022 (JP) 2022-199724

(51) Int. Cl. H01M 10/058; G01R 31/378; G01R 31/52; H01M 10/48

(52) U.S. Cl. CPC H01M 10/058; G01R 31/378; G01R 31/52; H01M 10/48

(57) ABSTRACT

It is an object of the present disclosure to provide a method for inspecting a battery in which the presence or absence of a short circuit can be determined with high accuracy. The above object is achieved by providing a method for inspecting a battery, the method comprising: a preparing step, a liquid injection step, a sealing step, and a short-circuit determination step, wherein the preparing step is a step of preparing an electrode assembly including a cathode active material layer and an anode active material layer, the electrode assembly has a non-opposed region other than a region where the cathode active material layer and the anode active material layer face each other, the liquid injection step is a step of injecting a liquid electrolyte into the electrode assembly to obtain a battery having a plurality of power generation units connected in series, the sealing step is a step of sealing the battery under reduced pressure, and the short-circuit determination step is a step of determining the presence or absence of a short circuit by at least one of the following methods (i) and (ii) before an initial charging, (i) the voltage of the power generation unit is measured at atmospheric pressure, and it is determined that a short circuit has occurred in the power generation unit when the measured value of the voltage of the power generation unit is 0V, and (ii) the voltage of the battery is measured at atmospheric pressure, and it is determined that a short circuit has occurred in the battery when the measured value of the voltage of the battery is lower than a reference value obtained by multiplying the number of power generation units included in the battery by an open-circuit voltage of the power generation unit unique to a material of the cathode active material layer and a material of the anode active material layer.

### TECHNICAL FIELD

The present disclosure relates to a method for inspecting a battery and a method for producing a battery.

### BACKGROUND ART

Various methods have been proposed as a method for inspecting a short circuit in a battery.

For example, Patent Literature 1 discloses a method for inspecting a short-circuit for a bipolar battery. The method includes a step of forming a layered product having a plurality of bipolar electrodes, a step of pressurizing the layered product, a step of measuring a measurement value corresponding to an electrostatic capacitance between a cathode termination electrode and an an anode termination electrode of the layered product, and a step of determining whether a short circuit has occurred in the layered product based on the measurement value.

Patent Literature 2 discloses a battery short-circuit detecting method. In this method, an electrode group in which a cathode plate, an anode plate, and a separator are laminated is housed in a battery case, helium gas is injected into the battery case, and a predetermined voltage is applied between a positive terminal and a negative terminal in the presence of helium to detect the presence or absence of a short circuit in the electrode group.

### CITATION LIST

### Patent Literatures

Patent Literature 1: Japanese Patent Application Laid-Open (JP-A) No. 2020-202019
Patent Literature 2: Japanese Patent Application Laid-Open (JP-A) No. H11-297368

### SUMMARY OF DISCLOSURE

### Technical Problem

There are cases where a foreign substance is mixed in the opposite portion of a cathode active material layer and an anode active material layer, and the foreign substance break through a separator, resulting in a short circuit. Thus, for example, in a bipolar battery, prior to injecting a liquid electrolyte, an electrode assembly is pressurized in the thickness direction, and a voltage is applied to a cathode and an anode at the start and end of the stack. By this method, the short circuit can be detected from a resistance obtained from a flowing current and the applied voltage.

On the other hand, in a non-opposed region other than the region where the cathode active material layer and the anode active material layer face each other, it is difficult to inspect the short circuit because the pressure is not applied during pressurization. If the foreign substance is present in the non-opposed region, the short circuit may occur when the inside of the battery is depressurized in a charged condition.

In addition, in a liquid injection step, foreign substance may be mixed into the battery. Therefore, it is required to perform a short-circuit inspection after the liquid injection step. However, after the liquid injection step, current does not concentrate on the short-circuit portion even when a voltage is applied, so that it is impossible to detect the short-circuit.

The present disclosure has been made in view of the above circumstances, and it is an object of the present disclosure to provide a method for inspecting a battery capable of determining the presence or absence of a short circuit with high accuracy.

### Solution to Problem

[1]

A method for inspecting a battery, the method comprising: a preparing step, a liquid injection step, a sealing step, and a short-circuit determination step, wherein
the preparing step is a step of preparing an electrode assembly including a cathode active material layer and an anode active material layer, the electrode assembly has a non-opposed region other than a region where the cathode active material layer and the anode active material layer face each other,
the liquid injection step is a step of injecting a liquid electrolyte into the electrode assembly to obtain a battery having a plurality of power generation units connected in series,
the sealing step is a step of sealing the battery under reduced pressure, and
the short-circuit determination step is a step of determining the presence or absence of a short circuit by at least one of the following methods (i) and (ii) before an initial charging,
(i) the voltage of the power generation unit is measured at atmospheric pressure, and it is determined that a short circuit has occurred in the power generation unit when the measured value of the voltage of the power generation unit is 0V, and
(ii) the voltage of the battery is measured at atmospheric pressure, and it is determined that a short circuit has occurred in the battery when the measured value of the voltage of the battery is lower than a reference value obtained by multiplying the number of power generation units included in the battery by an open-circuit voltage of the power generation unit unique to a material of the cathode active material layer and a material of the anode active material layer.

[2]

The method for inspecting a battery according to [1], wherein the electrode assembly comprises a plurality of stacked bipolar electrodes.

[3]

The method for inspecting a battery according to [1] or [2], wherein in the short-circuit determining step, after it is determined that a short circuit has occurred in the battery by the method according to (ii), the presence or absence of a short circuit is determined by the method according to (i) for each of the power generation units.

[4]

A method for inspecting a battery, the method comprising: a preparing step, a liquid injection step, a sealing step, and a short-circuit determination step, wherein
the preparing step is a step of preparing an electrode assembly including a cathode active material layer and an anode active material layer, the electrode assembly has a non-opposed region other than a region where the cathode active material layer and the anode active material layer face each other,
the liquid injection step is a step of injecting a into the electrode assembly to obtain a battery having a power generation unit,
the sealing step is a step of sealing the battery under reduced pressure, and
the short-circuit determination step is a step of determining the presence or absence of a short circuit by the following method (i) before an initial charging, (i) the voltage of the power generation unit is measured at atmospheric pressure, and it is determined that
a short circuit has occurred in the power generation unit when the measured value of the voltage of the power generation unit is 0V.

[5]

A method for producing a battery, the method comprising: an inspection step and a charging step, wherein the inspection step is a step of performing a method for inspecting a battery according to any one of [1] to [4], and the charging step is a step of performing an initial charging on the battery for which it is not determined that a short circuit has occurred.

### Advantageous Effects of Disclosure

The present disclosure has an effect that the presence or absence of a short circuit can be inspected with high accuracy.

### BRIEF DESCRIPTION OF DRAWINGS

FIG. 1 is a process flowchart illustrating a method for inspecting a battery according to a first embodiment of the present disclosure.

FIG. 2 is a schematic cross-sectional view illustrating an electrode assembly according to a first embodiment of the present disclosure.

FIG. 3 is a schematic cross-sectional view for explaining a liquid injection step in a first embodiment of the present disclosure.

FIG. 4 is a schematic cross-sectional view for explaining a sealing step in a first embodiment of the present disclosure.

FIG. 5 is a schematic cross-sectional view illustrating a short-circuit determination step in a first embodiment of the present disclosure.

FIGS. 6A and 6B are schematic cross-sectional views (exploded views) illustrating a method of manufacturing an electrode assembly according to a first embodiment of the present disclosure.

FIG. 7 is a process flowchart illustrating a method for inspecting a battery according to a second embodiment of the present disclosure.

### DESCRIPTION OF EMBODIMENTS

Hereinafter, the present disclosure will be described in detail with reference to the drawings. The figures shown below are examples, and the size of each part and the shape of each part may be exaggerated for ease of understanding.

### A. Method for Inspecting Battery (First Embodiment)

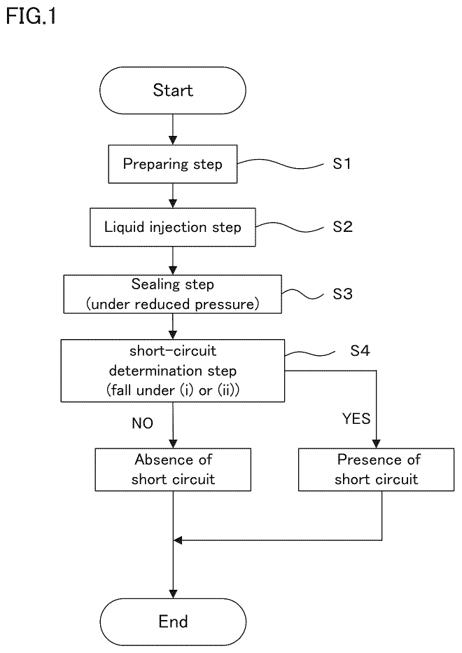

FIG. 1 is a process flowchart illustrating a method for inspecting a battery according to the present embodiment. As shown in FIG. 1, a method for inspecting a battery according to the present embodiment includes a preparing step (S1), a liquid injection step (S2), a sealing step (S3), and a short-circuit determination step (S4).

In this embodiment, in the sealing step (S3), the inside of battery is depressurized. Therefore, in the short-circuit determination step (S4), when battery is taken out at atmospheric pressure, all portions including the non-opposed region are pressurized. Therefore, the presence or absence of a short circuit is determined with high accuracy by at least one of the methods (i) and (ii) described below. In addition, foreign substance may be mixed in the liquid injection step (S2). It is possible to detect a short circuit caused by such a foreign substance. In particular, the presence or absence of a short circuit in the bipolar stacked battery is inspected with higher accuracy. Each step will be described in detail.

### 1. Preparing Step

This step is a step of preparing an electrode assembly including a cathode active material layer and an anode active material layer. The electrode assembly has a non-opposed region. The non-opposed region is a region other than the region where the cathode active material layer and the anode active material layer face each other when viewed from the z-axis direction.

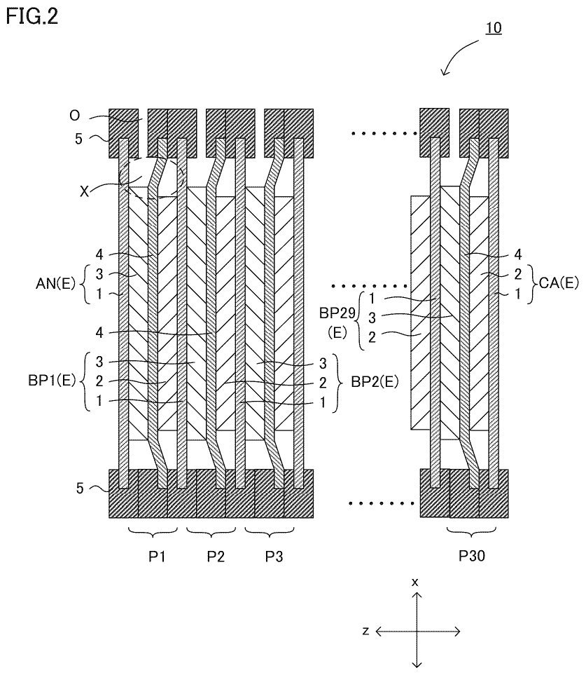

The electrode assembly according to the present embodiment includes two or more precursors of the power generation units. FIG. 2 is a schematic cross-sectional view illustrating the electrode assembly in the present disclosure. As shown in FIG. 2, the electrode assembly 10 preferably has a plurality of precursors P (P1 to P30) stacked along the z-axis. The precursor P of the power generation unit has a cathode active material layer 2, an anode active material layer 3 and a separator 4 arranged between the cathode active material layer 2 and the anode active material layer 3. The electrode assembly has a non-opposed region X other than the region where the cathode active material layer 2 and the anode active material layer 3 face each other.

As shown in FIG. 2, the electrode assembly 10 may include a plurality of electrodes E stacked in the z-axis direction. The electrode assembly 10 shown in FIG. 2 has bipolar electrodes BP (BP1 to BP29) as electrodes E. Further, the electrode assembly 10 includes a cathode end electrode CA and an anode end electrode AN. The bipolar BP comprises a current collector 1, the cathode active material layer 2 and the anode active material layer 3. The cathode active material layer 2 is arranged on one side of the current collector 1, and the anode active material layer 3 is arranged on the other side of current collector 1. The cathode end electrode CA has the current collector 1 and the cathode active material layer 2. The cathode active material layer 2 is arranged on one side of the current collector 1. The anode end-electrode AN has the current collector 1 and the anode active material layer 3. The anode active material layer 3 is arranged on one side of current collector 1.

The electrode assembly 10 in the present embodiment may have only one bipolar electrode BP or may have two or more. On the other hand, battery may not have a bipolar electrode.

In the present embodiment, as shown in FIG. 2, the precursors P (P1 to P30) are directly connected to each other. The precursors are independent of each other so that a liquid electrolyte do not flow through each other.

The precursor of one power generation unit may be configured using two bipolar electrodes. As shown in FIG. 2, for example, the precursor P2 of the power generation unit is composed of the cathode active material layer 2 in the bipolar electrode BP2, the anode active material layer 3 in the bipolar electrode BP1, and the separator 4 disposed therebetween.

As shown in FIG. 2, the frame-shaped sealing member 5 is preferably disposed along the outer edge of the current collector 1 when viewed from the z-axis. The sealing member is preferably a resin member. Examples of the resin constituting the resin member include thermoplastic resins. Examples of the thermoplastic resin include olefin-based resins such as polyethylene and polypropylene. As shown in FIG. 2, the sealing member 5 preferably has a through hole O for supplying a liquid electrolyte to the inside of the electrode assembly 10. As shown in FIG. 2, through hole O preferably extends along the x-axis.

The shape of the electrode assembly in plan view (the shape viewed from the z-axis direction) is not particularly limited, and examples thereof include quadrangles such as squares and rectangles. The length of one side of the battery in plan view may be, for example, equal to or greater than 30 cm, equal to or greater than 50 cm, or equal to or greater than 100 cm. On the other hand, the length of the one side is, for example, 200 cm or less.

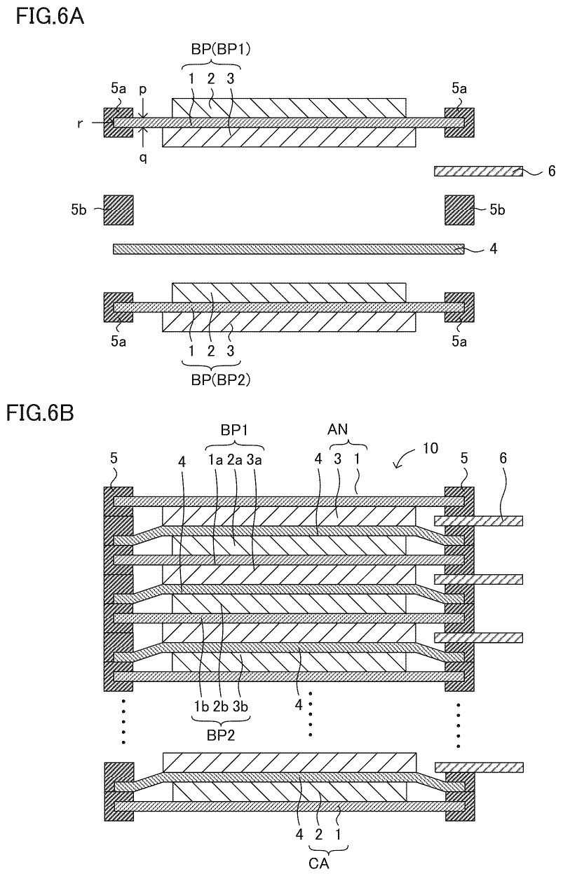

Methods for producing the electrode assembly are not particularly limited. FIG. 6 is a schematic cross-sectional view illustrating a method of fabricating the electrode assembly in the present disclosure. As shown in FIG. 6A, a plurality of bipolar electrodes BP are prepared. The bipolar electrode BP has a frame member 5a disposed along an outer edge of current collector 1 for forming a sealing member. When viewed from the z-axis, the frame member 5a is usually disposed along the entire outer periphery of the current collector 1. For example, when the outer edge shape of the current collector 1 is a quadrangle, the frame member 5a is disposed along the entire periphery of the outer edge of the quadrangle.

As shown in FIG. 6A, the anode active material layer 3 in the bipolar electrode BP1 and the cathode active material layer 2 in the bipolar electrode BP2 are opposed to each other via the separator 4. At this time, at least a part of the outer edge of the separator 4 is disposed between the frame members 5a. As shown in FIG. 6A, a nest 6 and a frame member (spacer) 5b are disposed between the frame member 5a in the bipolar electrode BP1 and the frame member 5a in the bipolar electrode BP2. Next, although not particularly shown, the cathode side end electrode CA and the anode side end electrode AN are stacked on the bipolar electrode BP1 and the bipolar electrode BP2 via the separator 4, respectively. Thereafter, the plurality of laminated frame members are welded to form a sealing member. In this way, as shown in FIG. 6B, the electrode assembly 10 in which the nest is inserted is obtained. A through hole formed electrode assembly is obtained by pulling out the nest.

### 2. Liquid Injection Step

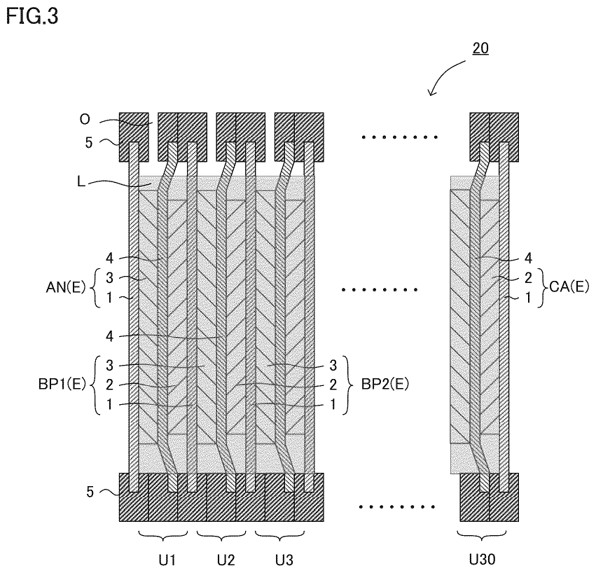

The liquid injection step in the present embodiment is a step of injecting a liquid electrolyte into the electrode assembly to obtain a battery having a plurality of power generation units connected in series. FIG. 3 is a schematic cross-sectional view for explaining the liquid injection step in the present embodiment. As shown in FIG. 3, the liquid electrolyte L is supplied to the inside of the electrode assembly 10 via the through hole O. As a result, the liquid electrolyte L is supplied to the cathode active material layers 2, the anode active material layers 3, and the separators 4. Consequently, the cathode active material layers 2, the anode active material layers 3, and the separators 4 are each impregnated with the liquid electrolyte L. In addition, a battery 20 having a plurality of power generation units U (from U1 to U30) connected in series is obtained. As shown in FIG. 3, the battery 20 is preferably a bipolar stacked battery.

The method of injecting the liquid electrolyte is not particularly limited, and for example, a known method using an injection device is used. As the liquid electrolyte, for example, a known organic liquid electrolyte used in a lithium-ion secondary battery can be used as appropriate.

### 3.Sealing Step

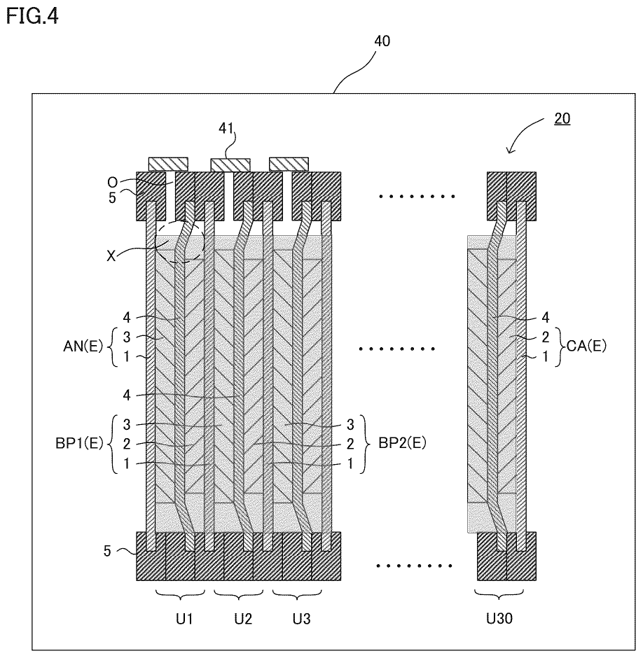

The sealing step in the present embodiment is a step of sealing the battery at a reduced pressure after the liquid injection step. FIG. 4 is a schematic cross-sectional view for explaining the sealing step in the present disclosure. For example, the battery 20 after the liquid injection step is placed in a chamber 40, and the inside of the chamber 40 is evacuated. Thereafter, as shown in FIG. 4, a sealing material 41 is disposed on the through hole O, and the sealing member 5 is welded to the sealing material 41. As a result, the battery 20 can be sealed in a reduced pressure, and all the portions including the non-opposed regions X are in a negative pressure condition. Therefore, a short-circuit can be detected by a short-circuit determination step described later.

### 4. Short-Circuit Determination Step

The method for inspecting a battery according to the present embodiment includes a short-circuit determination step. The short-circuit determination step is a step of determining the presence or absence of a short circuit by at least one of the following methods (i) and (ii) prior to the initial charging.
(i) the voltage of the power generation unit is measured at atmospheric pressure, and it is determined that a short circuit has occurred in the power generation unit when the measured value of the voltage of the power generation unit is 0V, and
(ii) the voltage of the battery is measured at atmospheric pressure, and it is determined that a short circuit has occurred in the battery when the measured value of the voltage of the battery is lower than a reference value obtained by multiplying the number of power generation units included in the battery by an open-circuit voltage of the power generation unit unique to a material of the cathode active material layer and a material of the anode active material layer.

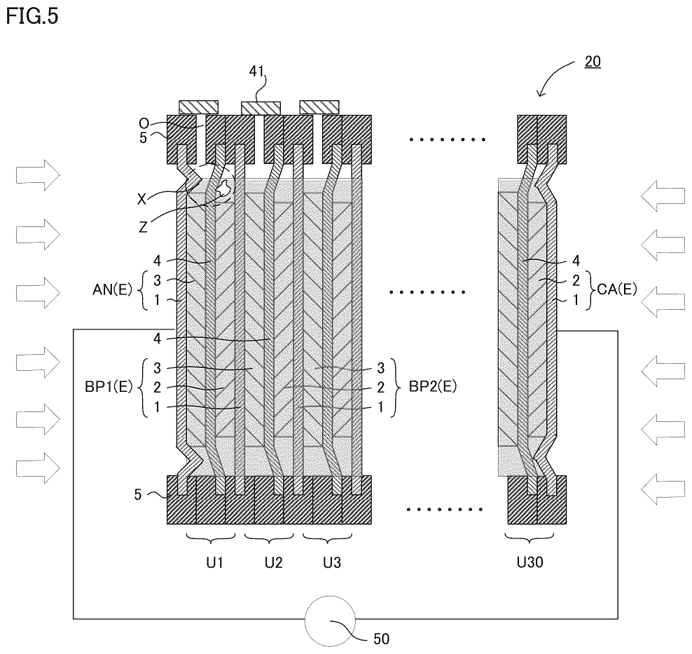

FIG. 5 is a schematic cross-sectional view illustrating a short circuit determination step in the present disclosure.

As shown in FIG. 5, when the chamber is opened after the sealing step, the outermost foil of the battery 20 (the current collector 1 of the cathode end electrode CA and the current collector 1 of the anode end electrode AN) is pushed by atmospheric pressure. At this time, the non-oppsed region X is also pushed by atmospheric pressure. When the foreign substance Z is mixed, the foreign substance Z is pressed against the separator 4. When the foreign substance Z is large, the separator 4 is broken. In this step, at least one of the voltage of the power generation unit and the voltage of the battery is measured at atmospheric pressure.

In the short-circuit determination step, when the measured voltage of the power generation unit is 0V, it may be determined that a short-circuit has occurred in the power generation unit (the method (i)).

After the liquid injection step, the difference between the natural potential of a cathode active material and the natural potential of an anode active material generate a material-specific open-circuit voltage in the respective power generation units.

However, in a power generation unit in which a foreign substance is mixed, a short circuit may occur. The voltage of the power generation unit in which the short circuit occurs is usually 0V. Therefore, when the measured voltage of the power generation unit is 0V, it can be determined that a short circuit has occurred. In addition, according to the above-described method (i), it is possible to detect the short circuit with high accuracy in order to determine whether or not the measured voltage is 0V.

The voltage of the power generation unit can be measured by measuring the voltage between the cathode terminal and the anode terminal of the power generation unit. The voltage may be measured by a conventionally known method.

In the short circuit determination step, when the measured voltage of the battery is lower than the reference value, it may be determined that a short circuit has occurred in the battery (the method (ii)). The reference value is a value obtained by multiplying the number of the power generation units included in the battery by the open-circuit voltage of the power generation unit unique to a material of the cathode active material layer and a material of the anode active material layer. According to the above-described method (ii), the presence or absence of a short circuit can be determined by measuring the total voltage of the battery without individually measuring the voltage of the power generation units.

If the battery is a bipolar stacked battery, the voltage of the battery 20 can be measured by measuring the total voltage between the current collector 1 of the cathode end electrode CA and the current collector 1 of the anode end electrode AN with the voltmeter 50, as shown in FIG. 5.

In the method of (ii), a reference V0 is used. The reference value V0 is a value obtained by multiplying the number (N) of the power generation units included in the battery by the open-circuit voltage (V1) of the power generation unit unique to a material of the cathode active material layer and a material of the anode active material layer. That is, the reference V0[V] is V1[V]×N[cell]. “The open-circuit voltage of the power generation unit unique to the material of the cathode active material layer and the material of the anode active material layer” is a natural potential difference generated during injection that is unique to the type of the cathode active material and the type of the anode active material. The open circuit voltage can be obtained by measuring in advance.

As described above, the voltage of the power generation unit in which the short circuit occurs is usually 0V. Therefore, when the battery has one short-circuited power generation unit, the measured voltage of the battery is a value obtained by multiplying the open-circuit voltage V1 of the power generation unit by N−1 (=V1× (N−1) [V]). When the battery has two short-circuited power generation units, the measured voltage of the battery is a value obtained by multiplying the open-circuit voltage V1 of the power generation unit by N−2 (=V1×(N−2) [V]).

For example, if the cathode active material is LFP (lithium ferric phosphate) and the anode active material is graphite, the open-circuit voltage of the power generation unit is measured to be about 0.1V. The battery 20 as shown in FIG. 5 has 30 power generation units. Therefore, the reference V0 is 0.1 [V]×30 [cell]=3 [V].

However, if the battery has one short-circuited power generation unit, the measured voltage of the battery will be about 2.9V. If battery has two short-circuited power generation units, the measured voltage of the battery will be approximately 2.8V.

In this way, it can be determined that a short circuit has occurred in the battery when the measured voltage V of the battery is lower than the reference value V0 (=V1[V]×N[cell]). In addition, it may be determined that a short circuit has occurred in the battery when the measured voltage V of the battery is equal to or less than V1 [V]× (N−1) [cell].

In the short-circuit determination step in the present embodiment, both methods (ii) and (i) may be combined. For example, by the method (ii), after it is determined that a short circuit has occurred in the battery, it is further possible to determine a short circuit for each of the power generation units by the method (i). As a result, it is possible to detect the power generation unit in which a short circuit has occurred in the stacked battery.

### B. Method for Inspecting Battery (Second Embodiment)

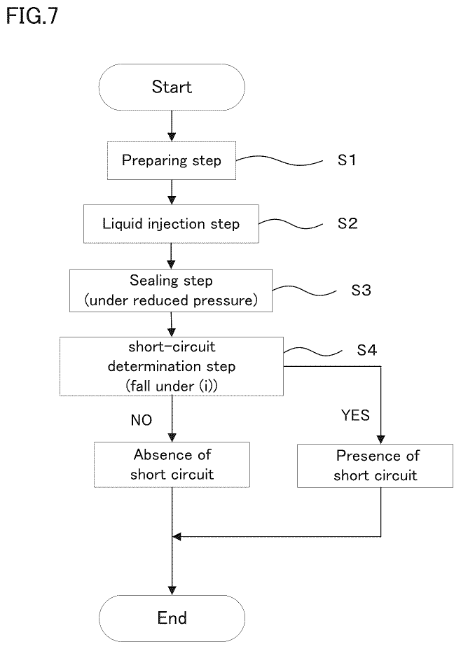

FIG. 7 is a process flowchart illustrating a method for inspecting a battery according to the present embodiment. As illustrated in FIG. 7, the method for inspecting a battery of the present embodiment includes a preparing step (S1), an injection step (S2), a sealing step (S3), and a short-circuit determination step (S4). Each step will be described in detail.

### 1. Preparing Step

This step is a step of preparing an electrode assembly including a cathode active material layer and an anode active material layer. The electrode assembly has a non-opposed region other than a region where the cathode active material layer and the anode active material layer face each other. The electrode assembly in the present embodiment may have only one precursor of the power generation unit. In addition, the electrode assembly according to the present embodiment may include two or more precursors of a power generation unit.

### 2. Liquid Injection Step

The liquid injection step in the present embodiment is a step of injecting a liquid electrolyte into the inside of the electrode assembly to obtain a battery having a power generation unit. The battery may be a single battery having one power generation unit. The battery may have two or more power generation units. When the battery includes a plurality of power generation units, they may be connected in series with each other. The plurality of power generation units may be connected in parallel to each other.

### 3. Sealing Step

The sealing step in the present embodiment is a step of sealing the battery at a reduced pressure after the liquid injection step. The sealing step can be performed in the same manner as in the first embodiment.

### 4. Short-Circuit Determination Step

The short-circuit determination step in the present embodiment is a step in which the presence or absence of a short-circuit is determined by the following method (i) before initial charging.

(i) At atmospheric pressure, the voltage of the power generation unit is measured, and when the measured voltage of the power generation unit is 0V, it is determined that a short circuit has occurred in the power generation unit.

The short-circuit determination step in the present embodiment can be performed in the same manner as the method (i) in the short-circuit determination step of the first embodiment. For example, in the case of a single battery, the voltages between the terminals of the cathode terminal and the anode terminal are measured. Thus, it is possible to determine whether a short circuit has occurred or not in the power generation unit (battery).

### C. Method for Producing Battery

Method for producing a battery includes an inspection step and a charging step.

### 1. Inspection Step

The inspection step is a step of inspecting a battery having a power generation unit. As a method of inspecting battery, the above-described method of inspecting battery can be employed.

### 2. Charging Step

The charging step is a step of performing the initial charging on the battery in which it is not determined that a short circuit has occurred. The battery in which no short circuit has occurred can be selected by the above-described inspection step. The battery can be manufactured by performing the initial charging on the selected battery according to a standard method.

For non-selected electrode assemblies, there is no need to charge the electrode assembly afterwards, thus eliminating waste in battery manufacturing process.

### 3.Battery

Specific examples of the battery include a secondary battery (for example, a lithium-ion secondary battery) and an electric double-layer capacitor. Applications of battery include, for example, power supplies for vehicles such as hybrid electric vehicle (HEV), plug-in hybrid electric vehicle (PHEV), battery electric vehicle (BEV), gasoline-powered vehicles, and diesel-powered vehicles. In particular, it is preferably used for a power supply for driving a hybrid electric vehicle (HEV), a plug-in hybrid electric vehicle (PHEV), or a battery electric vehicle (BEV). In addition, the battery may be used as a power source for a moving object (for example, a railroad, a ship, or an airplane) other than vehicles, or may be used as a power source for an electric appliance such as an information processing device.

### Examples

Hereinafter, the present disclosure will be further described with reference to Example.

### Example

As shown in FIG. 2, an electrode assembly 10 in which bipolar electrodes BP were stacked was prepared. In the bipolar type electrode BP, a cathode active material layer includes LFP (lithium ferric phosphate), and an anode active material layer includes graphite. As shown in FIG. 3, a liquid electrolyte was injected into the electrode assembly through the injection port O of the electrode assembly 10. This resulted in a bipolar stacked battery 20 having 30 power generation units U connected in series. From the open-circuit voltage 0.1V of the power generation unit measured in advance, the reference value is calculated as 3.0V (=0.1[V]×30 [cells]). At this time, a foreign substance having a length of 200 micrometers was introduced into the laminated battery through the injection port O. The bipolar stacked battery 20 was then placed in the chamber 40 and evacuated as shown in FIG. 4. As a result, the inside of the laminated battery 20 was depressurized. Next, the injection port O was sealed with the sealing material 41. Next, as shown in FIG. 5, the chamber 40 was opened to atmospheric pressure. Next, the voltage between the outermost foils (the current collector 1 of the cathode end electrode CA and the current collector 1 of the anode end electrode AN) was measured. Since the measured voltage was 2.9V, it was determined that a short circuit occurred in the battery. In addition, it can be inferred that there is only one power generation unit in which a short circuit has occurred.

The present disclosure is not limited to the above-described embodiments. The above-described embodiment is an example, and any one having substantially the same configuration as the technical idea described in the claims in the present disclosure and having the same operation and effect is included in the technical scope of the present disclosure.

### REFERENCE SIGNS LIST

1 . . . current collector
2 . . . cathode active material layer
3 . . . anode active material layer
4 . . . separator
5 . . . sealing member
6 . . . nest
10 . . . electrode assembly
20 . . . battery
O . . . through hole

What is claimed is:

1. A method for inspecting a battery, the method comprising:
a preparing step, a liquid injection step, a sealing step, and a short-circuit determination step, wherein
the preparing step is a step of preparing an electrode assembly including a cathode active material layer and an anode active material layer, the electrode assembly has a non-opposed region other than a region where the cathode active material layer and the anode active material layer face each other,
the liquid injection step is a step of injecting a liquid electrolyte into the electrode assembly to obtain a battery having a plurality of power generation units connected in series,
the sealing step is a step of sealing the battery under reduced pressure, and
the short-circuit determination step is a step of determining the presence or absence of a short circuit by at least one of the following methods (i) and (ii) before an initial charging,
(i) the voltage of the power generation unit is measured at atmospheric pressure, and it is determined that a short circuit has occurred in the power generation unit when the measured value of the voltage of the power generation unit is 0V, and
(ii) the voltage of the battery is measured at atmospheric pressure, and it is determined that a short circuit has occurred in the battery when the measured value of the voltage of the battery is lower than a reference value obtained by multiplying the number of power generation units included in the battery by an open-circuit voltage of the power generation unit unique to a material of the cathode active material layer and a material of the anode active material layer.

2. The method for inspecting a battery according to claim 1, wherein the electrode assembly comprises a plurality of stacked bipolar electrodes.

3. The method for inspecting a battery according to claim 1, wherein in the short-circuit determining step, after it is determined that a short circuit has occurred in the battery by the method according to (ii), the presence or absence of a short circuit is determined by the method according to (i) for each of the power generation units.

4. A method for inspecting a battery, the method comprising:
a preparing step, a liquid injection step, a sealing step, and a short-circuit determination step, wherein
the preparing step is a step of preparing an electrode assembly including a cathode active material layer and an anode active material layer, the electrode assembly has a non-opposed region other than a region where the cathode active material layer and the anode active material layer face each other,
the liquid injection step is a step of injecting a liquid electrolyte into the electrode assembly to obtain a battery having a power generation unit,
the sealing step is a step of sealing the battery under reduced pressure, and
the short-circuit determination step is a step of determining the presence or absence of a short circuit by the following method (i) before an initial charging,
(i) the voltage of the power generation unit is measured at atmospheric pressure, and it is determined that a short circuit has occurred in the power generation unit when the measured value of the voltage of the power generation unit is 0V.

5. A method for producing a battery, the method comprising:
an inspection step and a charging step, wherein
the inspection step is a step of performing a method for inspecting a battery according to claim 1, and
the charging step is a step of performing an initial charging on the battery for which it is not determined that a short circuit has occurred.
